(19) United States
(12) Patent Application Publication
(10) Pub. No.: US 2008/0101216 A1
(43) Pub. Date: May 1, 2008

(54) ORTHOGONAL FREQUENCY DIVISION MULTIPLEX (OFDM) SIGNAL EQUALIZIER

(75) Inventors: Masato Tanaka, Tokyo (JP); Hiroji Akahori, Tokyo (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI ELECTRIC INDUSTRY CO., LTD., Tokyo (JP)

(21) Appl. No.: 11/926,327

(22) Filed: Oct. 29, 2007

(30) Foreign Application Priority Data
Oct. 31, 2006 (JP) 2006296972

(51) Int. Cl. H04J 11/00; H03H 7/30

(52) U.S. Cl. 370/210; 375/229

(57) ABSTRACT

An equalizer equalizes a received orthogonal frequency division multiplex (OFDM) signal which includes periodic pilot symbols. The equalizer includes a channel estimation unit which estimates a frequency response the received OFDM signal, and an equalization circuit which equalizes the received OFDM signal in accordance with the frequency response estimated by the channel estimation circuit so as to output a resultant equalized OFDM signal. The channel estimation circuit determines complex gain amounts of respective propagation channels of the OFDM signal based on the pilot symbols, applies the complex gain amounts to a window function circuit which passes given complex gain amounts among the complex gain amounts which are contained within a predetermined time region window, and computes the frequency response based on the given complex gain amounts which are contained within the predetermined time region window.

### BACKGROUND OF THE INVENTION

1. Field of the Invention

The present invention generally relates to orthogonal frequency division multiplex (OFDM) signal transmission systems, and more particularly, the present invention relates to equalizer circuits utilized in the reception of OFDM signals.

2. Description of the Related Art

Orthogonal frequency division multiplex (OFDM) signal transmission techniques form the basis for a variety of signal broadcasting standards. For example, a television broadcast signal of the ISDB-T standard (Terrestrial Integrated Services Digital Broadcasting) is made up of thirteen OFDM segments, and the radio broadcast signal of the ISDB-T standard includes one to three OFDM segments. In ISDB-T, each segment is a packet of a predetermined number (e.g., 108 in Mode 1) of carrier waves corresponding to a transmission mode, and has a band of about 430 kHz. The carrier waves include a control information carrier and a data carrier. The control information carrier is modulated by a predetermined modulation method. The data carrier is modulated by a modulation method specified by the control information carrier and transmits content information of the broadcast signal.

In one segment of the ISDB-T standard, each carrier wave is modulated by an individual complex symbol (a so-called IQ symbol which denotes an orthogonal component of an information signal with a real number part and an imaginary number part) for every symbol period (the modulation period is about 1 ms), and multiplexed into one OFDM symbol and transmitted. In ISDB-T, 204 OFDM symbols constitute one transmission frame.

FIG. 2 is a diagram illustrating an example of the configuration of an ISDB-T transmission frame. In FIG. 2, carriers are arranged from left to right in ascending order of frequency, and OFDM symbols arranged from the top to bottom in time order. One complex symbol c(n, k) for modulating a carrier k during the period of a symbol number n is positioned in a cell where the carrier and the OFDM symbol intersect with each other. In other words, FIG. 2 shows the arrangement of the carriers of the complex symbols c(n, k) in order of frequency and time.

“SP” in FIG. 2 denotes scattered pilot (hereinafter referred to as “SP”) symbols which are reference values utilized in equalization of signals. The SP symbol is transmitted every three carriers, and every four symbol periods within each carrier. Also, the SP symbol is transmitted in a same symbol period every twelve carriers.

“TMCC” in FIG. 2 denotes a transmission and multiplexing configuration control (TMCC) signal of a predetermined control information carrier. The TMCC signal includes various control information, such as synchronization symbols denoting the synchronization timing of the frames, segment format identification symbols, segment type information, the modulation method information, and so on.

In FIG. 2, symbols which are not marked either “SP” or “TMCC” are data symbols for transmitting the content information of the broadcast signal.

One function of a broadcast signal receiver is to extract the SP symbols and calculate the frequency response H(n, k) of a transmission channel therefrom. In this manner, the phase and level of carrier data of an OFDM signal can be equalized.

FIG. 3 is a block diagram of a conventional OFDM signal equalizer as described in Japanese Patent Publication Laid-open No. 2004-153811 (JP '811).

As shown, the equalizer of JP '811 includes a fast Fourier transform circuit (FFT) 1, a dividing circuit 3, an SP signal extraction circuit 4, inverse fast Fourier transform circuits (IFFT) 5-1 and 5-2, low pass filters (LPF) 6-1 and 6-2, a composition circuit 7, and another FFT 8.

Referring to FIG. 3, the input signal IN, which is a digital complex baseband signal derived from a received OFDM broadcast signal, is subjected to Fourier transformation by the FFT 1 to generate carrier data Y(r, k). The carrier data Y(n, k) is supplied to the dividing circuit 3 and the SP signal extraction circuit 4.

The SP signal extraction circuit 4 extracts the SP symbols from the carrier data Y(n, k). The four most recent SP symbols (e.g., SP symbols i, i-1, i-2, i-3, where SP symbol “i” is the most recently received symbol) are supplied to the IFFT 5-1, whereas only the most recently received SP symbol (e.g., SP symbol i) is supplied to the IFFT 5-2.

The IFFT 5-1 subjects the four most recently received SP symbols (i, i-1, i-2, i-3) to inverse Fourier transformation so as to generate a first impulse response h1 (n, t) (t is a delay time) of the transmission channel. Likewise, the IFFT 5-2 subjects the most recently received SP symbol (i) to inverse Fourier transformation to generate a second impulse response h2(n, t) of the transmission channel. The first and second impulse responses h1(n, t) and h2(n, t) are supplied to the LPFs 6-1 and 6-2, respectively. The LPFs 6-1 and 6-2 remove high-frequency components of the impulse responses h1(n, t) and h2(n, t), and provide the resultant filtered impulse responses to the composition circuit 7.

The composition circuit 7 determines an impulse response of the transmission channel in according to a time zone of a multipath delay time. In particular, the composition circuit 7 utilizes the impulse response provided from the LPF 6-2 in a first time zone where a multipath delay time can be detected by an SP signal for the most recent symbol (e.g., symbol i). On the other hand, the composition circuit 7 utilizes the impulse response provided from the LPF 6-1 in a second time zone from the upper limit of the first time zone to the upper limit of a time zone where a delay time can be detected by the SP signals corresponding to the four most recent SP symbols (e.g., SP symbols i, i-1, i-2, i-3).

The impulse responses of the transmission channel are provided to the FFT 8 from the composition circuit 7. The FFT 8 subjects the impulse response to Fourier transformation such that the frequency response H(n, k) of the transmission channel is estimated. The frequency response H(n, k) is provided to the dividing circuit 3 where the carrier data Y(n, k) directly provided from the FFT 1 is divided by the frequency response H(n, k): Y(n, k)/H(n, k). Then, the result of the division by the dividing circuit 3 is output as carrier data OUT of the equalized OFDM signal.

In television broadcasting, an image signal is produced, for example, every 84 μs (which is equal to the symbol period divided by the number of intervals of the SP signals within one symbol). Generally, a target signal (principal wave) is first transmitted, and the image signal is then transmitted with delay. Problems can potentially arise in conventional equalizers when the reception order of the target and image signal transmission is reversed due to multipath propagation. Multipath propagation occurs due to reflections (e.g., off of buildings) present in the propagation channel.

### SUMMARY OF THE INVENTION

According to an aspect of the present invention, an equalizer is provided which equalizes a received orthogonal frequency division multiplex (OFDM) signal which includes periodic pilot symbols. The equalizer includes a channel estimation unit which estimates a frequency response the received OFDM signal, and an equalization circuit which equalizes the received OFDM signal in accordance with the frequency response estimated by the channel estimation circuit so as to output a resultant equalized OFDM signal. The channel estimation circuit determines complex gain amounts of respective propagation channels of the OFDM signal based on the pilot symbols, applies the complex gain amounts to a window function circuit which passes given complex gain amounts among the complex gain amounts which are contained within a predetermined time region window, and computes the frequency response based on the given complex gain amounts which are contained within the predetermined time region window.

### BRIEF DESCRIPTION OF THE DRAWINGS

The above and other aspects and features of the present invention will become readily apparent from the detailed description that follows, with reference to the accompanying drawings, in which:

FIG. 1 is a block diagram of an equalizer corresponding to one or more embodiments of the present invention;

FIG. 2 is a diagram showing an example of the configuration an ISDB-T standard transmission frame;

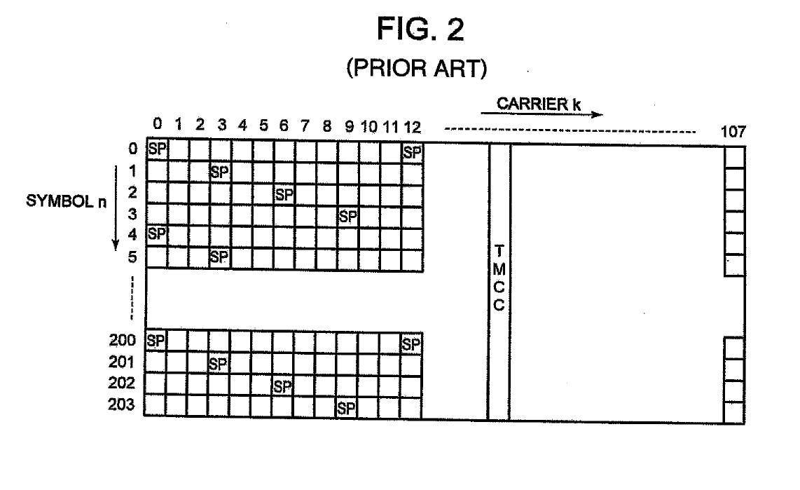

FIG. 3 is a block diagram of a conventional equalizer; and

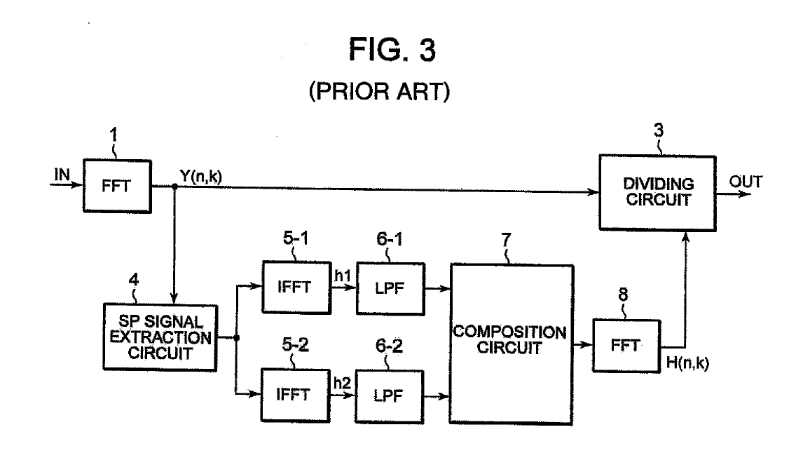

FIGS. 4A to 4D are timing diagrams for use in explaining an operation of the equalizer illustrated in FIG. 1 according to one or more embodiments of the present invention.

### DETAILED DESCRIPTION OF EMBODIMENTS

The present invention will now be described by way of preferred, but non-limiting, embodiments of the invention. The referenced drawings are presented for illustrative purposes only, and are not intended to limit the scope of the invention.

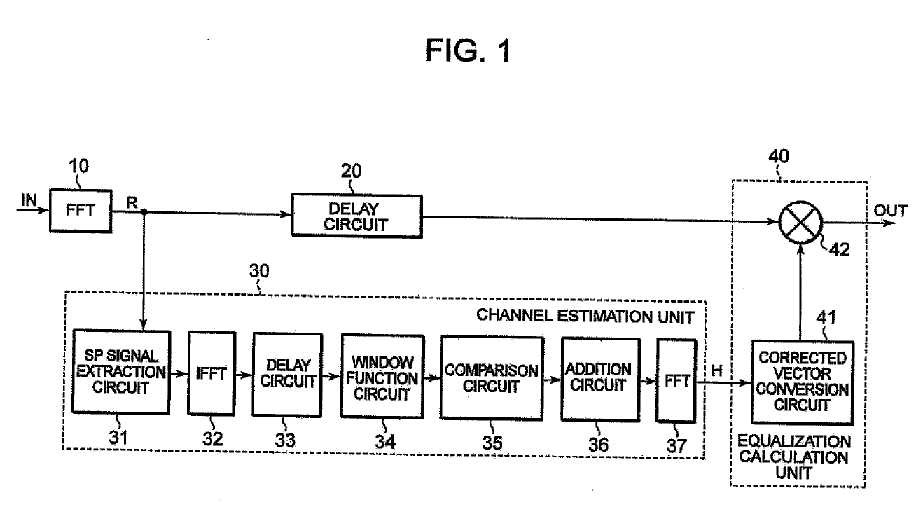

FIG. 1 is a block diagram of an equalizer corresponding to one or more embodiments of the present invention.

The equalizer of this example includes a Fast Fourier Transform circuit (FFT) 10, a delay circuit 20, a channel estimation unit 30 and an equalization calculation unit 40.

Referring to FIG. 1, the input signal IN, which is a digital complex baseband signal derived from a received OFDM broadcast signal, is subjected to Fourier transformation by the FFT 10 to generate reception signal R. The reception signal R is supplied to the delay circuit 20 and the channel estimation circuit 30.

The delay circuit 20 may be configured, for example, by a random access memory (RAM), so as to delay the reception signal R provided from the FFT 10 for a time corresponding to one symbol period. The thus delayed reception signal R is then output to the equalization calculation unit 40.

The channel estimation unit 30 estimates a frequency response H of a transmission channel in accordance with the reception signal R provided from the FFT 10. This aspect of the embodiments will be explained in more detail later herein.

The equalization calculation circuit 40 corrects the delayed reception signal R by utilizing the frequency response H of the transmission channel estimated by the channel estimation unit 30. More particularly, the calculation circuit 40 functions to equalize the phase and level of the reception signal R, and outputs the result as demodulated data OUT.

The channel estimation circuit 30 includes an SP signal extraction circuit 31, an IFFT circuit 32, a delay circuit 33, a window function circuit 34, a comparison circuit 35, an addition circuit 36 and an FFT circuit 37.

The SP signal extraction circuit 31 extracts an SP symbol from the reception signal R in which the SP symbol and data symbols are mixed.

The IFFT 32 performs a discrete inverse Fourier transformation having an estimable delay time width in accordance with the SP symbol extracted by the SP signal extraction circuit 31. In particular, the IFFT determines a complex gain amount for each arrival path (propagation channel) to transform the SP symbol to an SP signal of a time region.

The delay circuit 33, which may be configured, for example, by a RAM, delays the SP signal output from the IFFT 32 for a time corresponding to one symbol period and supplies the thus delayed signal to the window function circuit 34.

The window function circuit 34 cuts a signal of a given time width (“a-b”) out of the SP signal for one symbol period provided from the delay circuit 33. Here, “a” is one symbol period, and “b” is a middle region of the symbol period within which an image signal is estimated to be located. This aspect of the embodiment will be described in greater detail later herein.

The comparison circuit 35 compares an electric power per path from the complex gain amount output from the window function circuit 34 to a relative threshold value. In addition, the comparison circuit outputs the complex gain amount of the path as is when the complex gain amount exceeds the threshold value, and outputs a complex gain amount of 0 when the complex gain does not exceed the threshold value.

The addition circuit 36 outputs the output of the comparison circuit 35 after adding a predetermined number “X” thereto.

The FFT 37 transforms the output signal of the addition circuit 36 into a frequency domain signal, and outputs the resultant frequency response H of the transmission channel.

The equalization calculation unit 40 includes a corrected vector conversion circuit 41 and a multiplication circuit 42. The corrected vector conversion circuit 41 extracts the phase component for the transmission channel estimation corresponding to each sub-carrier. The multiplication circuit 42 multiplies the reception signal R (which has been delayed by the delay circuit 20) by the output of the corrected vector conversion circuit 41 in the form of a complex number, and outputs resultant demodulated data OUT.

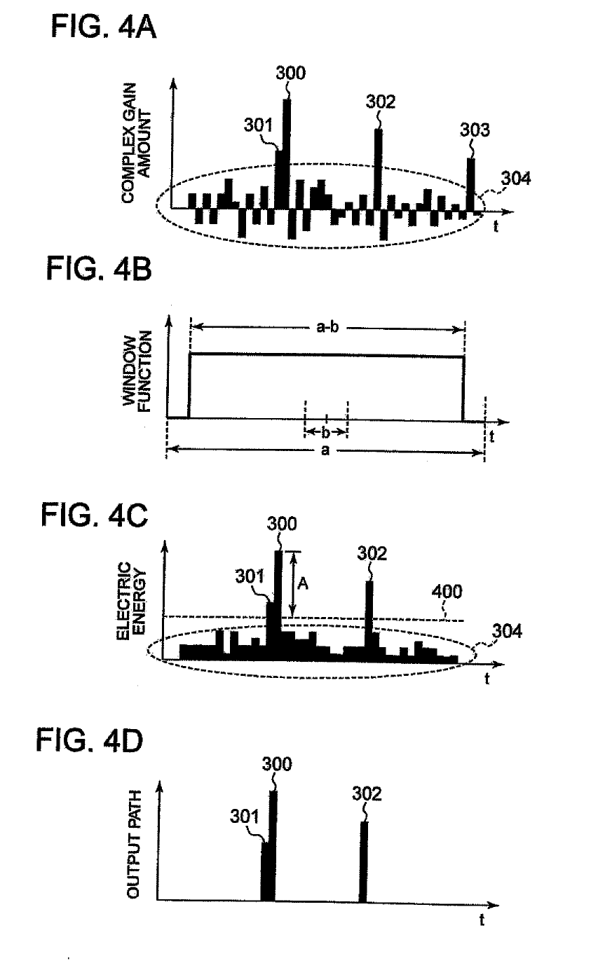

The operation of the equalizer illustrated in FIG. 1 will be described below in more detail with further reference to the diagrams of FIGS. 4A to 4D.

Referring to FIG. 1, the input signal IN of the OFDM signal (which has been converted to a digital complex baseband signal) is subjected to Fourier transformation by the FFT 10, to generate a reception signal R(n, k). The reception signal R(n, k) is supplied to the delay circuit 20 and the channel estimation unit 30.

The reception signal R(n, k) is delayed by the delay circuit 20 for a predetermined time period (for example, a time period corresponding to one symbol period), and the resultant delayed signal is output to the equalization calculation unit 40.

In the meantime, the reception signal R(n, k) provided to the channel estimation unit 30 is input to the SP signal extraction circuit 31. Here, pilot symbols are extracted. As discussed previously, the pilot symbols are dispersed and arranged in the reception signal R at a predetermined period. For example, assume for simplicity that the data array in a symbol number n of the reception signal R is DDDPDDDPDDDPDDD, where P is a pilot symbol and D is a data symbol. The extraction circuit 31 may function to replace each D with 0 (zero). In this case, the data array of the signal after extraction is 000P000P000P000.

The reception signal R(n, k) from which the pilot symbols are extracted is provided to the IFFT 32 where it is subjected to the discrete inverse Fourier transformation having an estimable delay time width, and a complex gain amount for each arrival path is determined. The complex gain amount contains noise and calculation errors as well as the transfer function of the transmission channel.

FIG. 4A is a graph showing the complex gain amount for each arrival path obtained by the discrete inverse Fourier transform circuit 32. A path 300 denoting the maximum complex gain amount is estimated to be the OFDM signal which has arrived directly at the receiver from a transmitter. Paths 301 to 303 are estimated to be the OFDM signals which have been reflected by obstacles such as buildings between the transmitter and the receiver (and thus were detoured relative to the path 300). Moreover, paths 304 are estimated to be signals produced by noise and/or calculation errors.

The complex gain amount output from the IFFT 32 is provided to and held in the delay circuit 33.

In the OFDM symbol having the pilot symbols arranged at equal subcarrier intervals, a theoretically estimable delay time width of the complex gain amount is a delay time width up to a reciprocal number of the subcarrier interval of the pilot symbols with respect to an effective OFDM symbol length. In terrestrial digital broadcasting, one pilot symbol is placed for 12 subcarriers. Therefore, the theoretically estimable delay time width of the complex gain amount is one twelfth of the effective OFDM symbol length.

The complex gain amount held in the delay circuit 33 is output in response to a read request and provided to the window function circuit 34. FIG. 4B is a graph showing the response characteristics of the window function circuit 34. As shown in this graph, the window function circuit 34 cuts out and outputs the complex gain amounts corresponding to the period of a symbol length “a-b” which is shorter than one twelfth of the effective OFDM symbol length of the provided complex gain amount.

Thus, the path 303 present which is time-wise spaced from the path 300 (estimated to be the directly arriving OFDM signal) is removed by the window function circuit 34 and is not output therefrom.

The complex gain amounts cut by the window function circuit 34 are provided to the comparison circuit 35, and electric power for each path is determined. FIG. 4C is a diagram illustrating the electrical energy of each path after begin subjected to the window function circuit 34. Then, the path 300 having the maximum electric power is determined, and a relative threshold value 400 is set (for example, at a predetermined power A less then the maximum) from the maximum electric power.

The paths 300 to 302 each having an electric power which is equal to or more than the threshold value 400 are extracted. Then, the complex gain amounts of the extracted paths are output as they are from the comparison circuit 35, while 0 is output for the paths that have not been extracted. Therefore, the paths output from the comparison circuit 35 to the addition circuit 36 are as shown in FIG. 4D.

The addition circuit 36 outputs the output of the comparison circuit 35 after adding the predetermined number thereto. As described above, the theoretically estimable delay time width of the complex gain amount is the delay time width up to the reciprocal number of the subcarrier interval of the pilot symbols with respect to the effective OFDM symbol length. Moreover, since the time width is narrowed by the window function circuit 34, the complex gain amount in which the noise and calculation errors are reduced only has the narrowed delay time width in the comparison circuit 35. Therefore, it is desirable to put some values into all Fourier transform point numbers in order to estimate the transmission channels for all the subcarriers through Fourier transform. Thus, the addition circuit 36 adds 0 to the time region after the delay time width obtained by the comparison of the threshold values. When a value other than 0 is added to the time region after the delay time width obtained from the comparison circuit 35, this means that the arrival path is present at the delay time corresponding to the time position where the value is added. The addition of 0 also means no presence of the arrival path at the delay time.

The signal in the time region to which the predetermined number is added by the addition circuit 36 is provided to the FFT 37 and transformed into a frequency domain signal. The frequency domain signal obtained by the transformation is provided to the corrected vector conversion circuit 41 of the equalization calculation unit 40 as the estimated frequency response H of the transmission channel.

The corrected vector conversion circuit 41 extracts the phase component for transmission channel estimation corresponding to each subcarrier. The value for transmission channel estimation has a real number part and an imaginary number part, and the phase component is generated by a calculation using the real number part and the imaginary number part. Then, it is output after transformation into a value which is the complex conjugate of the phase component. That is, the real number part is output as is while the imaginary number part is output with its sign inverted.

The multiplication circuit 42 multiplies, in complex number, the output of the corrected vector conversion circuit 41 by the value of the reception signal R in which each subcarrier obtained by the fast Fourier transformation of the received OFDM signal is delayed for one symbol. Thus, demodulated data OUT is output in which a phase rotation caused in the transmission channel is cancelled.

As described above, the equalizer of embodiments of the present invention includes a window function circuit which cuts out the complex gain amounts within a given time region. Complex gain amounts in the time width a-b centered at the middle of one symbol period “a” are cut out by the window function circuit, and then the frequency response H is generated by Fourier transformation, thereby generating the frequency response H in which the image signal located within the time width b centered at the middle of the symbol period is erased. Thus, if the reception signal R is equalized using the frequency response H generated by the channel estimation unit equipped with the window function circuit as described above, it is possible to reduce deterioration of characteristics due to the image signal in the OFDM signal.

The present invention is not limited to the embodiment described above, and various modifications can be made thereto while still falling within the scope of the appended claims.

For example, the delay circuit 33 is not limited to delaying the output signal of the IFFT 32 for one symbol period. Further, the delay circuit 33 may have a configuration including a plurality of delay circuits for delaying the output signal of the IFFT 32 one symbol period and two symbol periods, respectively. This makes it possible to select proper delay characteristics in accordance with transmission characteristics.

Also, while the present embodiment has been described using dedicated the circuit units configured of hardware (such as the SP signal extraction circuit 31), it is also possible to implement a configuration which performs processing under software control using a processor such as a digital signal processor (DSP). As one skilled in the art will appreciate, the embodiments and functional blocks thereof may be implemented by hardware, software, and/or combinations thereof. Thus, the term “circuit” is defined herein as to include hardware, software, and/or combinations thereof.

What is claimed is:

1. An equalizer which equalizes a received orthogonal frequency division multiplex (OFDM) signal which includes periodic pilot symbols, said equalizer comprising:
a channel estimation unit which estimates a frequency response the received OFDM signal; and
an equalization circuit which equalizes the received OFDM signal in accordance with the frequency response estimated by the channel estimation circuit, and which outputs a resultant equalized OFDM signal;
wherein the channel estimation circuit determines complex gain amounts of respective propagation channels of the OFDM signal based on the pilot symbols, applies the complex gain amounts to a window function circuit which passes given complex gain amounts among the complex gain amounts which are contained within a predetermined time region window, and computes the frequency response based on the given complex gain amounts which are contained within the predetermined time region window.

2. The equalizer of claim 1, wherein the channel estimation unit comprises:
an extraction circuit which extracts the pilot symbols from the received OFDM signal;
an inverse Fourier transform circuit which subjects the extracted pilot symbols to inverse Fourier transformation to calculate a complex gain amount for each of the propagation channels;
a delay circuit which delays the complex gain amounts calculated by the inverse Fourier transform circuit, and which applies the delayed complex gain amounts to the window function circuit;
a comparison circuit which compares an electric power of the given complex gain amounts passed by the window function circuit with reference value, and the filtered complex gain amounts among the given complex gain amounts which exceed the reference value; and
a Fourier transform circuit which subjects the filter complex gains to Fourier transformation to obtain the frequency response of the transmission channel.

3. The equalizer of claim 2, further comprising an addition circuit operatively interposed between the comparison circuit and the Fourier transform circuit, wherein the addition circuit adds a predetermined value to the filtered complex gain amounts, and supplies an addition result to the Fourier transform circuit.

4. The equalizer according to claim 1, wherein the time region window has a time width a-b, where “a” is one symbol period, and “b” is less than “a”.

5. The equalizer according to claim 1, further comprising a delay circuit which delays the received OFDM signal, and applies the OFDM signal to the equalization circuit.

6. The equalizer according to claim 1, further comprising a second delay circuit which delays the received OFDM signal, and applies the OFDM signal to the equalization circuit.

7. The equalizer according to claim 6, wherein respective delay times of the second delay circuit and the delay circuit of the channel estimation circuit each correspond to one symbol period.

8. The equalizer according to claim 1, wherein the OFDM signal is Fourier transformed digital complex baseband signal derived from a received OFDM broadcast signal.
